(19) United States
(12) Patent Application Publication
(10) Pub. No.: US 2023/0413509 A1
(43) Pub. Date: Dec. 21, 2023

(54) METHOD FOR PREPARING MEMORY DEVICE WITH MULTILAYERED CAPACITOR DIELECTRIC STRUCTURE

(71) Applicant: NANYA TECHNOLOGY CORPORATION, New Taipei City (TW)

(72) Inventors: CHIH-HSIUNG HUANG, NEW TAIPEI CITY (TW); KAI-HUNG LIN, TAOYUAN CITY (TW); JYUN-HUA YANG, TAIPEI CITY (TW)

(21) Appl. No.: 17/845,849

(22) Filed: Jun. 21, 2022

(51) Int. Cl. H01L 27/108

(52) U.S. Cl. CPC H01L 27/10855; H01L 27/10814; H01L 27/10823; H01L 27/10876; H01L 27/10885

(57) ABSTRACT

The present disclosure provides a method for preparing a memory device. The method includes forming a doped region in a semiconductor substrate, and forming a word line across the doped region such that a first source/drain region and a second source/drain region are formed in the doped region and at opposite sides of the word line. The method also includes forming a bit line over and electrically connected to the first source/drain region, and forming a capacitor over and electrically connected to the second source/drain region. The formation of the capacitor includes forming a bottom electrode, forming a capacitor dielectric structure over the bottom electrode, and forming a top electrode over the capacitor dielectric structure.

### TECHNICAL FIELD

The present disclosure relates to a method for preparing a memory device, and more particularly, to a method for preparing a memory device with a multilayered capacitor dielectric structure.

### DISCUSSION OF THE BACKGROUND

Due to structural simplicity, dynamic random access memories (DRAMs) can provide more memory cells per unit chip area than other types of memories, such as static random access memories (SRAMs). A DRAM is constituted by a plurality of DRAM cells, each of which includes a capacitor for storing information and a transistor coupled to the capacitor for regulating when the capacitor is charged or discharged. During a read operation, a word line (WL) is asserted, turning on the transistor. The enabled transistor allows the voltage across the capacitor to be read by a sense amplifier through a bit line (BL). During a write operation, the data to be written is provided on the BL while the WL is asserted.

To satisfy the demand for greater memory storage, the dimensions of the DRAM memory cells have continuously shrunk so that the packing densities of these DRAMs have increased considerably. However, the manufacturing and integration of memory devices involve many complicated steps and operations. Integration in memory devices becomes increasingly complicated. An increase in complexity of manufacturing and integration of the memory device may cause deficiencies. Accordingly, there is a continuous need to improve the structure and the manufacturing process of memory devices so that the deficiencies can be addressed, and the performance can be enhanced.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

In one embodiment of the present disclosure, a memory device is provided. The memory device includes a semiconductor substrate having an active region, and a word line extending across the active region. The memory device also includes a first source/drain region and a second source/drain region disposed in the active region and at opposite sides of the word line, and a bit line disposed over and electrically connected to the first source/drain region. The memory device further includes a capacitor disposed over and electrically connected to the second source/drain region. The capacitor includes a bottom electrode, a top electrode, and a capacitor dielectric structure disposed between the bottom electrode and the top electrode. The capacitor dielectric structure includes a first metal oxide layer, a second metal oxide layer disposed over the first metal oxide layer, and a third metal oxide layer disposed over the second metal oxide layer. The first metal oxide layer, the second metal oxide layer, and the third metal oxide layer include materials that are different from each other.

In an embodiment, the first metal oxide layer comprises ZrO₂, and the second metal oxide layer comprises Al₂O₃. In an embodiment, the third metal oxide layer comprises ZrO₂ doped with a dopant selected from the group consisting of Hf, Ta, La, Gd, Y, Sc, Ga, and lanthanide elements. In an embodiment, a concentration of the dopant in the third metal oxide layer is less than a concentration of Zr in the third metal oxide layer. In an embodiment, an atomic percentage of the dopant in the third metal oxide layer is less than 20%.

In an embodiment, the capacitor dielectric structure further includes a fourth metal oxide layer disposed over the third metal oxide layer, and a fifth metal oxide layer disposed over the fourth metal oxide layer, wherein the first metal oxide layer, the fourth metal oxide layer, and the fifth metal oxide layer comprise materials that are different from each other. In an embodiment, the fourth metal oxide layer and the second metal oxide layer comprise Al₂O₃. In an embodiment, the fifth metal oxide layer and the third metal oxide layer comprise ZrO₂ doped with a dopant selected from the group consisting of Hf, Ta, La, Gd, Y, Sc, Ga, and lanthanide elements.

In another embodiment of the present disclosure, a memory device is provided. The memory device includes a semiconductor substrate having an active region, and a word line extending across the active region. The memory device also includes a first source/drain region and a second source/drain region disposed in the active region and at opposite sides of the word line, and a bit line disposed over and electrically connected to the first source/drain region. The memory device further includes a capacitor disposed over and electrically connected to the second source/drain region. The capacitor includes a bottom electrode, a top electrode, and a capacitor dielectric structure disposed between the bottom electrode and the top electrode. The capacitor dielectric structure includes a first metal oxide layer, a second metal oxide layer disposed over the first metal oxide layer, and a third metal oxide layer disposed over the second metal oxide layer. The third metal oxide layer includes ZrO₂ doped with a first dopant selected from the group consisting of Hf, Ta, La, Gd, Y, Sc, Ga, and lanthanide elements.

In an embodiment, a crystallinity of the first metal oxide layer is higher than a crystallinity of the third metal oxide layer. In an embodiment, the top electrode and the bottom electrode of the capacitor include TiN. In an embodiment, the first metal oxide layer includes ZrO₂, and the second metal oxide layer includes Al₂O₃.

In an embodiment, the capacitor dielectric structure further includes a fourth metal oxide layer disposed over the third metal oxide layer, and the fourth metal oxide layer includes Al₂O₃. In an embodiment, the capacitor dielectric structure further includes a fifth metal oxide layer disposed over the fourth metal oxide layer, and the fifth metal oxide layer includes ZrO₂ doped with a second dopant selected from the group consisting of Hf, Ta, La, Gd, Y, Sc, Ga, and lanthanide elements. In an embodiment, the first dopant and the second dopant are the same.

In yet another embodiment of the present disclosure, a method for preparing a memory device is provided. The method includes forming a doped region in a semiconductor substrate, and forming a word line across the doped region such that a first source/drain region and a second source/drain region are formed in the doped region and at opposite sides of the word line. The method also includes forming a bit line over and electrically connected to the first source/drain region, and forming a capacitor over and electrically connected to the second source/drain region. The formation of the capacitor includes forming a bottom electrode, forming a capacitor dielectric structure over the bottom electrode, and forming a top electrode over the capacitor dielectric structure. The formation of the capacitor dielectric structure includes forming a first metal oxide layer, forming a second metal oxide layer over the first metal oxide layer, and forming a third metal oxide layer over the second metal oxide layer. The first metal oxide layer, the second metal oxide layer, and the third metal oxide layer include materials that are different from each other.

In an embodiment, the first metal oxide layer is formed by depositing ZrO₂, the second metal oxide layer is formed by depositing Al₂O₃, and the third metal oxide layer is formed by depositing ZrO₂ with a dopant selected from the group consisting of Hf, Ta, La, Gd, Y, Sc, Ga, and lanthanide elements. In an embodiment, the method further includes repeating the forming the second metal oxide layer and the forming the third metal oxide layer one or more times before the top electrode is formed.

In an embodiment, the first metal oxide layer, the second metal oxide layer, and the third metal oxide layer are formed by atomic layer deposition (ALD) processes. In an embodiment, a number of ALD cycles of the dopant occupies less than about 20% of a number of total ALD cycles of the third metal oxide layer.

Embodiments of a memory device and method for preparing the same are provided in the disclosure. In some embodiments, the memory device includes a capacitor having a multilayered capacitor dielectric structure. The capacitor dielectric structure includes a first metal oxide layer, a second metal oxide layer, and a third metal oxide layer. In some embodiments, the first metal oxide layer, the second metal oxide layer, and the third metal oxide layer include materials that are different from each other. Since the capacitor dielectric structure includes multiple layers of different dielectric materials, the materials of the capacitor dielectric structure can be selected to reduce the current leakage of the memory device while maintaining acceptable capacitance. As a result, the overall device performance may be improved.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a top view illustrating a memory device, in accordance with some embodiments.

FIG. 2 is a cross-sectional view illustrating the memory device along the sectional line A-A′ in FIG. 1, in accordance with some embodiments.

FIG. 3 is an enlarged view of a portion of the memory device in FIG. 1, in accordance with some embodiments.

FIG. 4 is an enlarged view of a portion of the memory device in FIG. 1, in accordance with alternative embodiments.

FIG. 5 is an enlarged view of a portion of the memory device in FIG. 1, in accordance with yet alternative embodiments.

FIG. 6 is a flow diagram illustrating a method for preparing a memory device, in accordance with some embodiments.

FIG. 7 is a flow diagram illustrating a method for preparing a capacitor dielectric structure of a capacitor in a memory device, in accordance with some embodiments.

FIG. 8 is a top view illustrating an intermediate stage of forming active regions in a semiconductor substrate during the formation of the memory device, in accordance with some embodiments.

FIG. 9 is a cross-sectional view illustrating an intermediate stage in the formation of the memory device along the sectional line A-A′ in FIG. 8, in accordance with some embodiments.

FIG. 10 is a top view illustrating an intermediate stage of forming trenches across the active regions during the formation of the memory device, in accordance with some embodiments.

FIG. 11 is a cross-sectional view illustrating an intermediate stage in the formation of the memory device along the sectional line A-A′ in FIG. 10, in accordance with some embodiments.

FIG. 12 is a top view illustrating an intermediate stage of forming word lines in the trenches during the formation of the memory device, in accordance with some embodiments.

FIG. 13 is a cross-sectional view illustrating an intermediate stage in the formation of the memory device along the sectional line A-A′ in FIG. 12, in accordance with some embodiments.

FIG. 14 is a top view illustrating an intermediate stage of forming a dielectric cap layer over the word lines during the formation of the memory device, in accordance with some embodiments.

FIG. 15 is a cross-sectional view illustrating an intermediate stage in the formation of the memory device along the sectional line A-A′ in FIG. 14, in accordance with some embodiments.

FIG. 16 is a top view illustrating an intermediate stage of forming bit lines over the dielectric cap layer during the formation of the memory device, in accordance with some embodiments.

FIG. 17 is a cross-sectional view illustrating an intermediate stage in the formation of the memory device along the sectional line A-A′in FIG. 16, in accordance with some embodiments.

FIG. 18 is a top view illustrating an intermediate stage of forming air gaps on sidewalls of the bit lines during the formation of the memory device, in accordance with some embodiments.

FIG. 19 is a cross-sectional view illustrating an intermediate stage in the formation of the memory device along the sectional line A-A′ in FIG. 18, in accordance with some embodiments.

FIG. 20 is a top view illustrating an intermediate stage of forming a dielectric layer covering the bit lines and the air gaps during the formation of the memory device, in accordance with some embodiments.

FIG. 21 is a cross-sectional view illustrating an intermediate stage in the formation of the memory device along the sectional line A-A′ in FIG. 20, in accordance with some embodiments.

FIG. 22 is a top view illustrating an intermediate stage of forming conductive contacts in the dielectric layer during the formation of the memory device, in accordance with some embodiments.

FIG. 23 is a cross-sectional view illustrating an intermediate stage in the formation of the memory device along the sectional line A-A′ in FIG. 22, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

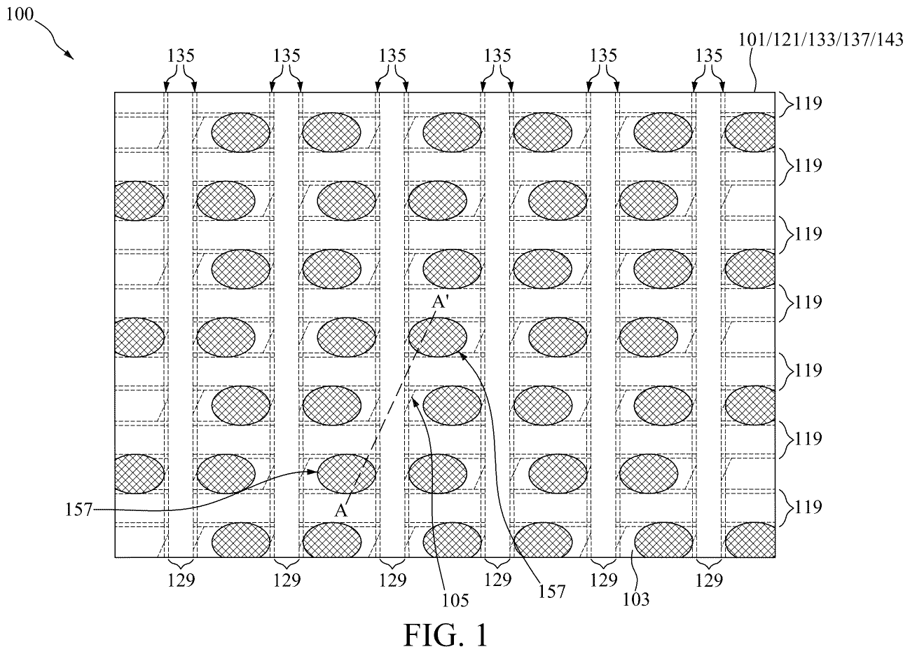

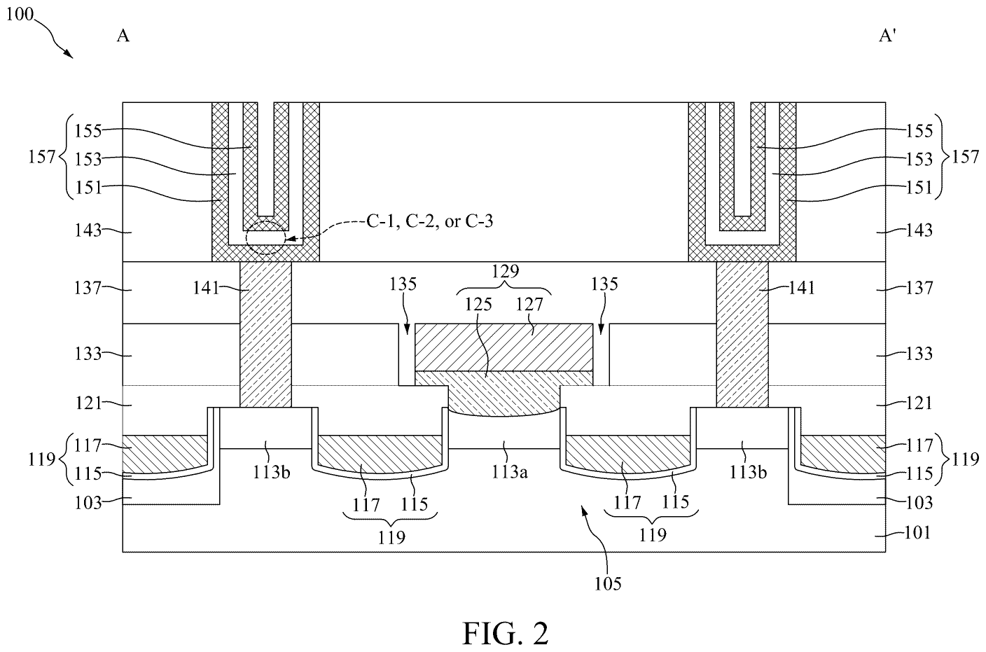

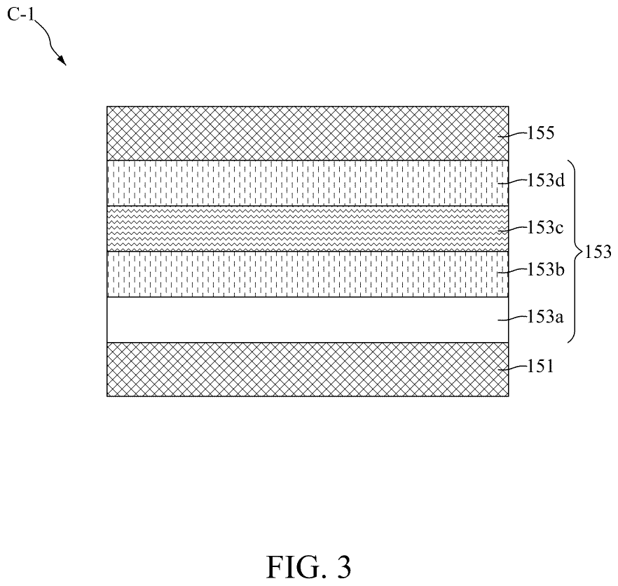

FIG. 1 is a top view illustrating a memory device 100, FIG. 2 is a cross-sectional view illustrating the memory device 100 along the sectional line A-A′ in FIG. 1, and FIGS. 3, 4 and 5 are enlarged views of the portion C-1 (or C-2 or C-3) of the capacitor 157 in the memory device 100, in accordance with some embodiments.

As shown in FIGS. 1 and 2, the memory device 100 includes a semiconductor substrate 101, an isolation structure 103 disposed in the semiconductor substrate 101 defining a plurality of active regions 105, a plurality of word lines 119 (i.e., the gate structures) extending across the active regions 105, and a plurality of source/drain regions 113a and 113b in the active regions 105 separated by the word lines 119. In some embodiments, each of the active regions 105 includes two source/drain regions 113b and one source/drain region 113a disposed between the source/drain regions 113b. Moreover, each of the word lines 119 includes a gate dielectric layer 115 and a gate electrode 117 surrounded by the gate dielectric layer 115.

The memory device 100 also includes a dielectric cap layer 121 covering the word lines 119, a dielectric layer 133 disposed over the dielectric cap layer 121, and a plurality of bit lines 129 penetrating through the dielectric layer 133 and the dielectric cap layer 121 to electrically connect to the source/drain regions 113a. In some embodiments, each of the bit line 129 includes a lower bit line layer 125 and an upper bit line layer 127 disposed over the lower bit line layer 125. In some embodiments, the bit lines 129 are separated from the dielectric layer 133 by air gaps 135.

The memory device 100 further includes a dielectric layer 137 disposed over the dielectric layer 133, a plurality of conductive contacts 141 penetrating through the dielectric cap layer 121 and the dielectric layers 133 and 137 to electrically connect to the source/drain regions 113b, and a dielectric layer 143 disposed over the dielectric layer 137. In addition, the memory device 100 includes a plurality of capacitors 157 disposed in the dielectric layer 143 to electrically connect to the source/drain regions 113b through the conductive contacts 141, as shown in FIGS. 1 and 2 in accordance with some embodiments.

In some embodiments, each of the capacitors 157 includes a bottom electrode 151, a top electrode 155 disposed over and surrounded by the bottom electrode 151, and a capacitor dielectric structure 153 disposed between and in direct contact with the bottom electrode 151 and the top electrode 155.

According to one embodiment of the present disclosure shown in FIG. 3, the capacitor dielectric structure 153 of the portion C-1 has a configuration in which four metal oxide layers are laminated. In some embodiments, a first metal oxide layer 153a is disposed over the bottom electrode 151, a second metal oxide layer 153b is disposed over the first metal oxide layer 153a, a third metal oxide layer 153c is disposed over the second metal oxide layer 153b, and a fourth metal oxide layer 153d is disposed over the third metal oxide layer 153c. In some embodiments, the first metal oxide layer 153a is in direct contact with the bottom electrode 151, and the fourth metal oxide layer 153d is in direct contact with the top electrode 155.

In some embodiments, the materials of the bottom electrode 151 and the top electrode 155 include TiN. In some embodiments, the material of the first metal oxide layer 153a includes ZrO₂, the material of the second metal oxide layer 153b includes Al₂O₃, the material of the third metal oxide layer 153c includes ZrO₂ doped with a dopant selected from the group consisting of Hf, Ta, La, Gd, Y, Sc, Ga, and lanthanide elements, and the material of the fourth metal oxide layer 153d includes Al₂O₃. In some embodiments, the first metal oxide layer 153a, the second metal oxide layer 153b, the third metal oxide layer 153c, and the fourth metal oxide layer 153d are formed by deposition processes, such as atomic layer deposition (ALD) processes.

Moreover, in some embodiments, the concentration of the dopant selected from the group consisting of Hf, Ta, La, Gd, Y, Sc, Ga, and lanthanide elements in the third metal oxide layer 153c is less than the concentration of Zr in the third metal oxide layer 153c. For example, an atomic percentage of the dopant selected from the group consisting of Hf, Ta, La, Gd, Y, Sc, Ga, and lanthanide elements in the third metal oxide layer 153c is less than 20%, this can be achieved by having the number of ALD cycles of the dopant occupies less than about 20% of the number of total ALD cycles of the third metal oxide layer 153c. In some embodiments, the crystallinity of the first metal oxide layer 153a is higher than the crystallinity of the third metal oxide layer 153c.

By using ZrO₂ doped with a dopant selected from the group consisting of Hf, Ta, La, Gd, Y, Sc, Ga, and lanthanide elements as the material of the third metal oxide layer 153c, the crystallinity of the third metal oxide layer 153c can be reduced, compared to the crystallinity of ZrO₂, and thus the current leakage can be reduced. In addition, since the atomic percentage of the dopant selected from the group consisting of Hf, Ta, La, Gd, Y, Sc, Ga, and lanthanide elements in the third metal oxide layer 153c is less than 20%, the capacitance of the capacitor 157 can be maintained at a high level needed for device performance. As a result, the overall device performance may be improved.

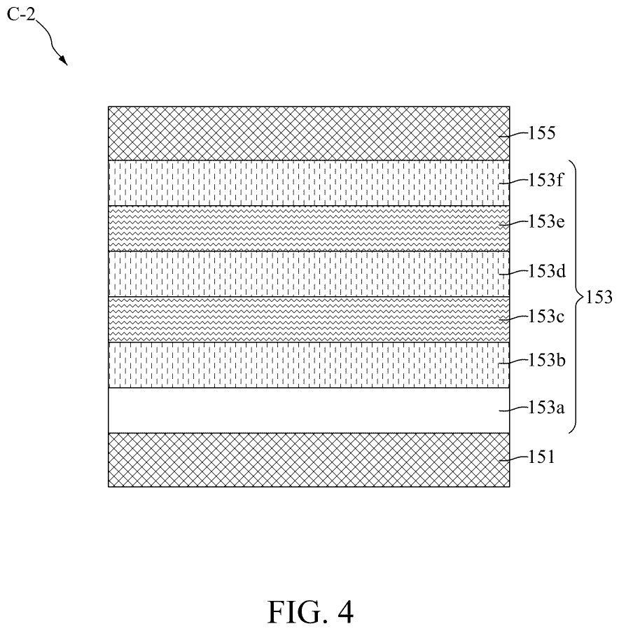

According to an alternative embodiment of the present disclosure shown in FIG. 4, the capacitor dielectric structure 153 of the portion C-2 has a configuration in which six metal oxide layers are laminated. The configuration of the capacitor dielectric structure 153 of the portion C-2 is similar to the configuration of the capacitor dielectric structure 153 of the portion C-1, and the difference there between is that a fifth metal oxide layer 153e and a sixth metal oxide layer 153f is disposed between the fourth metal oxide layer 153d and the top electrode 155. In some embodiments, the sixth metal oxide layer 153f is in direct contact with the top electrode 155.

In some embodiments, the material of the fifth metal oxide layer 153e includes ZrO₂ doped with a dopant selected from the group consisting of Hf, Ta, La, Gd, Y, Sc, Ga, and lanthanide elements, and the material of the sixth metal oxide layer 153f includes Al₂O₃. In some embodiments, the materials of the fifth metal oxide layer 153e and the third metal oxide layer 153c are the same (i.e., ZrO₂ doped with the same dopant selected from the group consisting of Hf, Ta, La, Gd, Y, Sc, Ga, and lanthanide elements), and the material of the sixth metal oxide layer 153f and the fourth metal oxide layer 153d are the same. In some embodiments, the dopant used in the formation of the fifth metal oxide layer 153e can be different from the dopant used in the formation of the third metal oxide layer 153c, but both of them are selected from the group consisting of Hf, Ta, La, Gd, Y, Sc, Ga, and lanthanide elements.

Some processes used to form the fifth metal oxide layer 153e and the sixth metal oxide layer 153f are similar to, or the same as, those used to from the third metal oxide layer 153c and the fourth metal oxide layer 153d and are not repeated herein. Moreover, similar to the third metal oxide layer 153c, the concentration of the dopant selected from the group consisting of Hf, Ta, La, Gd, Y, Sc, Ga, and lanthanide elements in the fifth metal oxide layer 153e is less than the concentration of Zr in the fifth metal oxide layer 153e. For example, an atomic percentage of the dopant selected from the group consisting of Hf, Ta, La, Gd, Y, Sc, Ga, and lanthanide elements in the fifth metal oxide layer 153e is less than 20%, this can be achieved by having the number of ALD cycles of the dopant occupies less than about 20% of the number of total ALD cycles of the fifth metal oxide layer 153e. In some embodiments, the crystallinity of the first metal oxide layer 153a is higher than the crystallinity of the fifth metal oxide layer 153e.

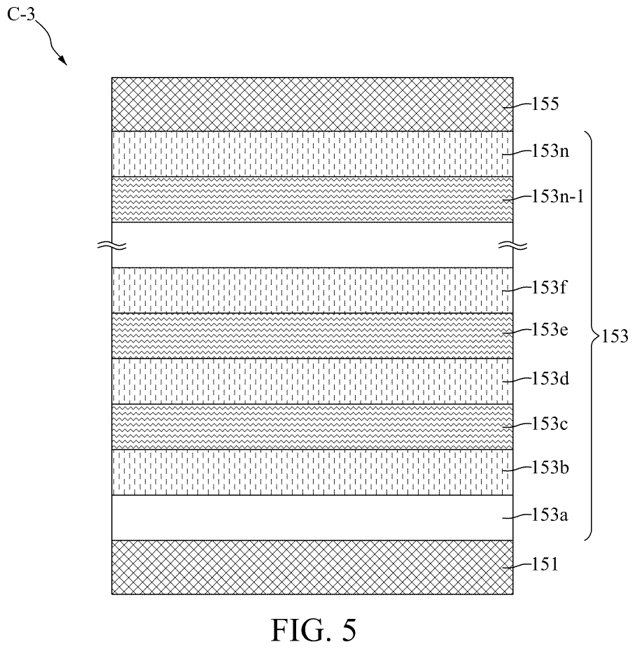

According to an alternative embodiment of the present disclosure shown in FIG. 5, the capacitor dielectric structure 153 of the portion C-3 has a configuration in which a plurality of “n” metal oxide layers are laminated. In some embodiments, a pair of metal oxide layers including a lower layer and an upper layer are repeatedly deposited between the metal oxide layer 153f and the top electrode 155 in the portion C-3, the above-mentioned lower layer includes ZrO₂ doped with a dopant selected from the group consisting of Hf, Ta, La, Gd, Y, Sc, Ga, and lanthanide elements, and the above-mentioned upper layer includes Al₂O₃. Details of this embodiment of the portion C-3 are similar to the previous embodiments of the portions C-1 and C-2, and thus are not repeated.

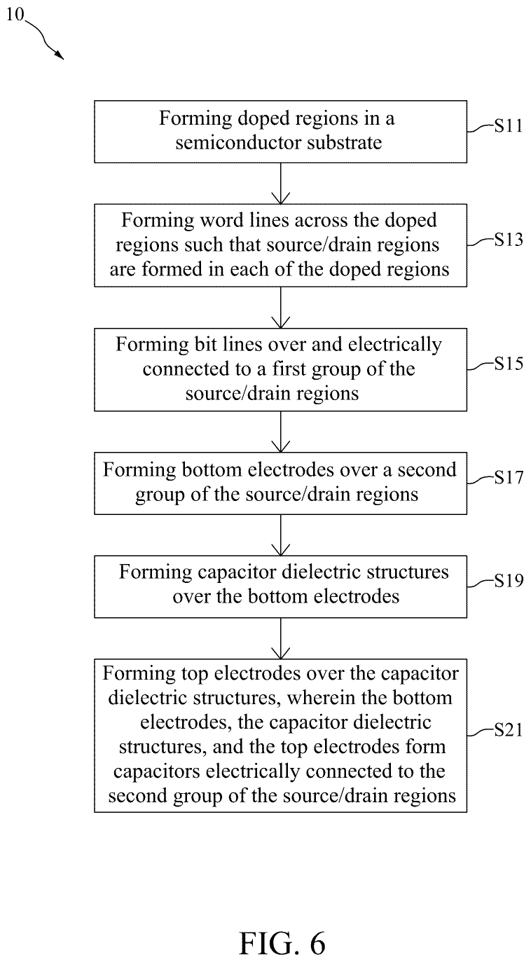

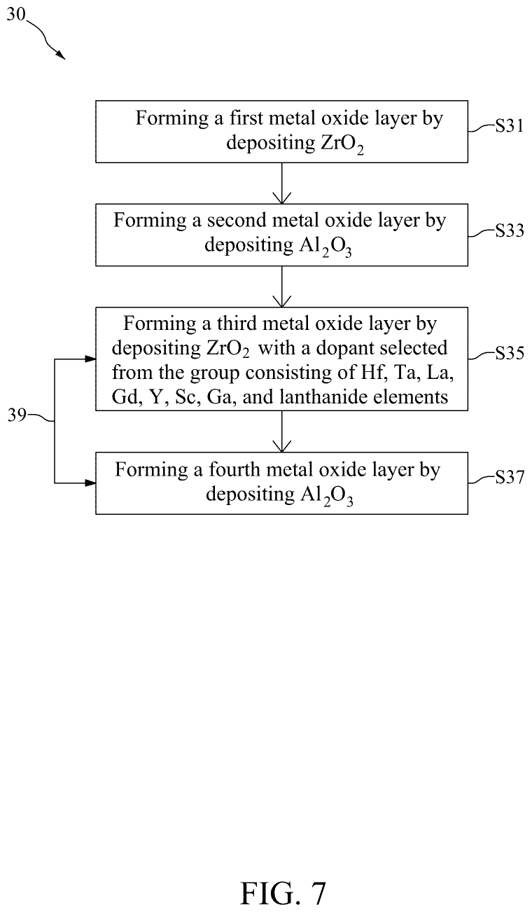

FIG. 6 is a flow diagram illustrating a method 10 for preparing the memory device 100, and the method 10 includes steps S11, S13, S15, S17, S19 and S21, in accordance with some embodiments. The steps S11 to S21 of FIG. 6 are elaborated in connection with the following figures. FIG. 7 is a flow diagram illustrating a method 30 for preparing the capacitor dielectric structure 153 of the capacitor 157 in the memory device 100, and the method 30 includes steps S31, S33, S35, S37 and S39, in accordance with some embodiments.

As mentioned above in connection with FIGS. 3-5, the method 30 begins at step S31 where a first metal oxide layer is formed by depositing ZrO₂. Next, at step S33, a second metal oxide layer is formed by depositing Al₂O₃. Then, a third metal oxide layer is formed by depositing ZrO₂ with a dopant selected from the group consisting of Hf, Ta, La, Gd, Y, Sc, Ga, and lanthanide elements at step S35. At step S37, a fourth metal oxide layer is formed by depositing Al₂O₃. After the step S37, the formation of the capacitor dielectric structure 153 can be finished, and the layers of the capacitor dielectric structure 153 are shown as the portion C-1 in FIG. 3.

In some embodiments, after the step S37, the steps S35 and S37 can be sequentially repeated, as indicated by the directional process arrow S39. If the steps S35 and S37 are repeated one time, the layers of the capacitor dielectric structure 153 are shown as the portion C-2 in FIG. 4. If the steps S35 and S37 are repeated more than one time, the layers of the capacitor dielectric structure 153 are shown as the portion C-3 in FIG. 5.

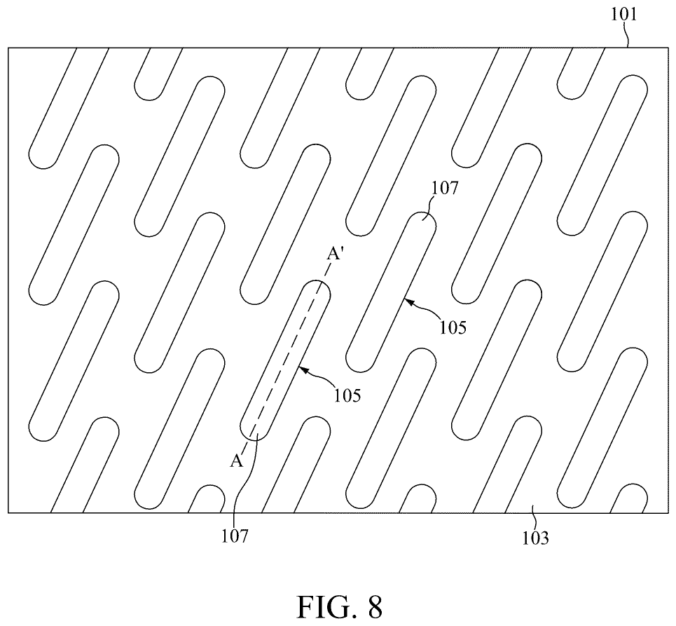

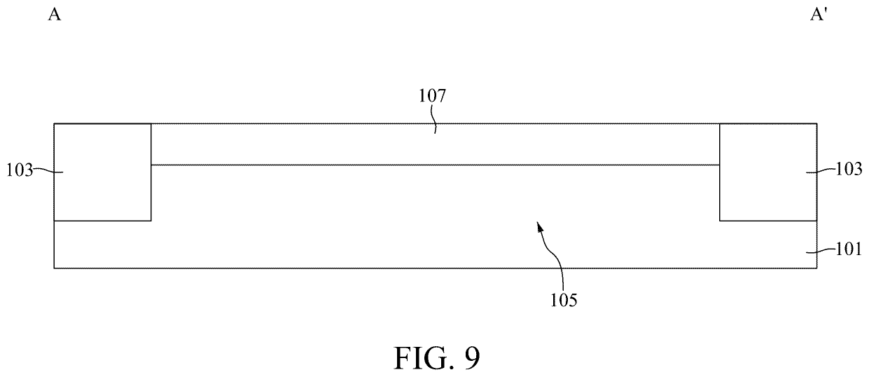

FIGS. 8, 10, 12, 14, 16, 18, 20 and 22 are top views illustrating intermediate stages in the formation of the memory device 100, and FIGS. 9, 11, 13, 15, 17, 19, 21 and 23 are cross-sectional views illustrating intermediate stages in the formation of the memory device 100, in accordance with some embodiments. It should be noted that FIGS. 9, 11, 13, 15, 17, 19, 21 and 23 are cross-sectional views along the sectional line A-A′ of FIGS. 8, 10, 12, 14, 16, 18, 20 and 22, respectively.

As shown in FIGS. 8 and 9, the semiconductor substrate 101 is provided. The semiconductor substrate 101 may be a semiconductor wafer such as a silicon wafer. Alternatively or additionally, the semiconductor substrate 101 may include elementary semiconductor materials, compound semiconductor materials, and/or alloy semiconductor materials. Examples of the elementary semiconductor materials may include, but are not limited to, crystal silicon, polycrystalline silicon, amorphous silicon, germanium, and/or diamond. Examples of the compound semiconductor materials may include, but are not limited to, silicon carbide, gallium arsenic, gallium phosphide, indium phosphide, indium arsenide, and/or indium antimonide. Examples of the alloy semiconductor materials may include, but are not limited to, SiGe, GaAsP, AlInAs, AlGaAs, GaInAs, GaInP, and/or GaInAsP.

In some embodiments, the semiconductor substrate 101 includes an epitaxial layer. For example, the semiconductor substrate 101 has an epitaxial layer overlying a bulk semiconductor. In some embodiments, the semiconductor substrate 101 is a semiconductor-on-insulator substrate which may include a substrate, a buried oxide layer over the substrate, and a semiconductor layer over the buried oxide layer, such as a silicon-on-insulator (SOI) substrate, a silicon germanium-on-insulator (SGOI) substrate, or a germanium-on-insulator (GOI) substrate. Semiconductor-on-insulator substrates can be fabricated using separation by implantation of oxygen (SIMOX), wafer bonding, and/or other applicable methods.

Still referring to FIGS. 8 and 9, the isolation structure 103 is formed in the semiconductor substrate 101 to define the active regions 105, and the isolation structure 103 is a shallow trench isolation (STI) structure, in accordance with some embodiments. In addition, the isolation structure 103 may be made of silicon oxide, silicon nitride, silicon oxynitride or another applicable dielectric material, and the formation of the isolation structure 103 may include forming a patterned mask (not shown) over the semiconductor substrate 101, etching the semiconductor substrate 101 to form openings (not shown) by using the patterned mask as a mask, depositing a dielectric material in the openings and over the semiconductor substrate 101, and polishing the dielectric material until the semiconductor substrate 101 is exposed.

Moreover, doped regions 107 are formed in the active regions 105 defined by the isolation structure 103. The respective step is illustrated as the step S11 in the method 10 shown in FIG. 6. In some embodiments, the doped regions 107 are formed by one or more ion implantation processes, and P-type dopants, such as boron (B), gallium (Ga), or indium (In), or N-type dopants, such as phosphorous (P) or arsenic (As), can be implanted in the active regions 105 to form the doped regions 107, depending on the conductivity type of the memory device 100. In addition, the doped regions 107 will become the source/drain regions of the memory device 100 in the subsequent processes.

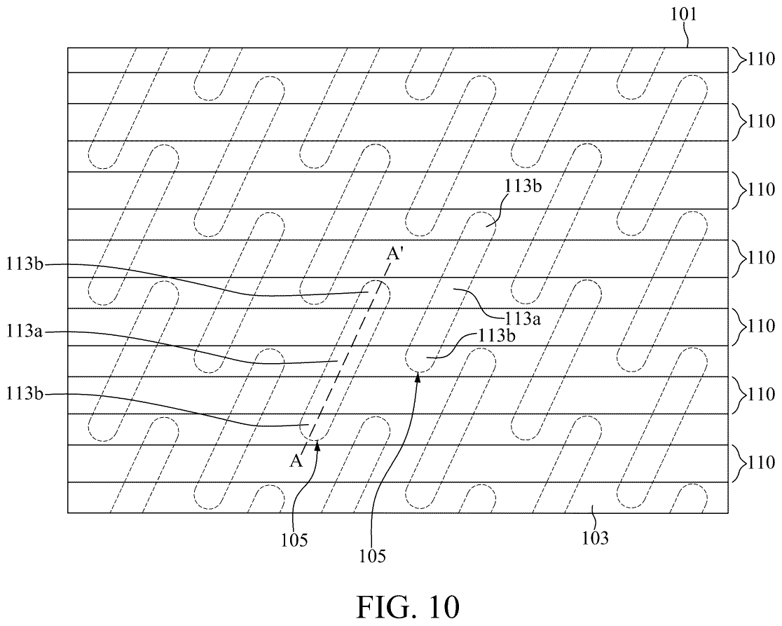

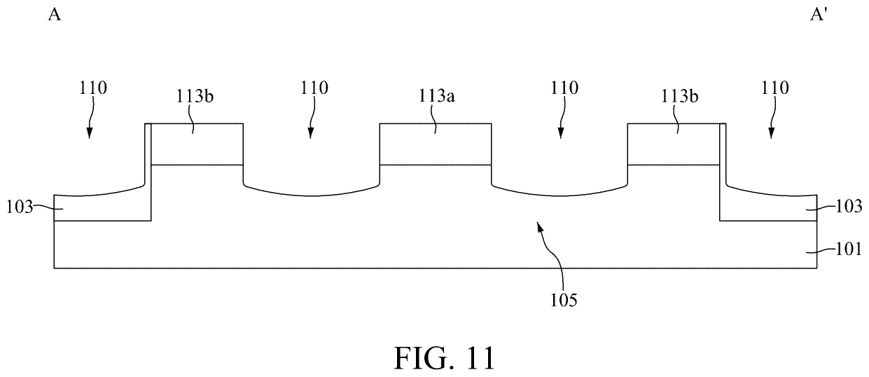

After the doped regions 107 are formed, the semiconductor substrate 101 is etched to form a plurality of trenches 110, as shown in FIGS. 10 and 11 in accordance with some embodiments. In some embodiments, the trenches 110 are parallel to each other. In some embodiments, the trenches 110 extending across the doped regions 107 in the active regions 105 to form the source/drain regions 113a and 113b.

In some embodiments, the source/drain regions 113b are located at the opposite end portions of the active regions 105, and the source/drain regions 113a are located at the middle portions of the active regions 105. The formation of the trenches 110 may include forming a patterned mask (not shown) over the semiconductor substrate 101, and etching the semiconductor substrate 101 by using the patterned mask as a mask. After the trenches 110 are formed, the pattered mask may be removed.

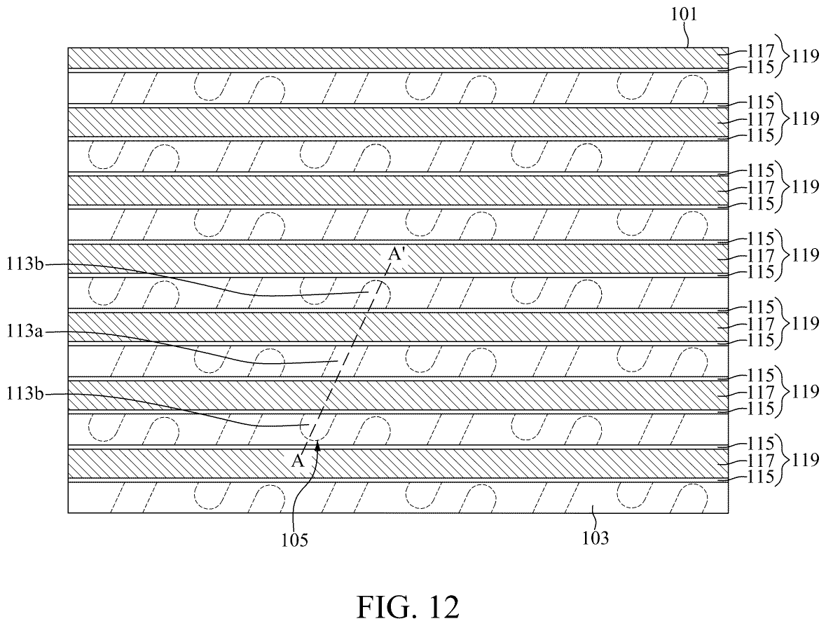

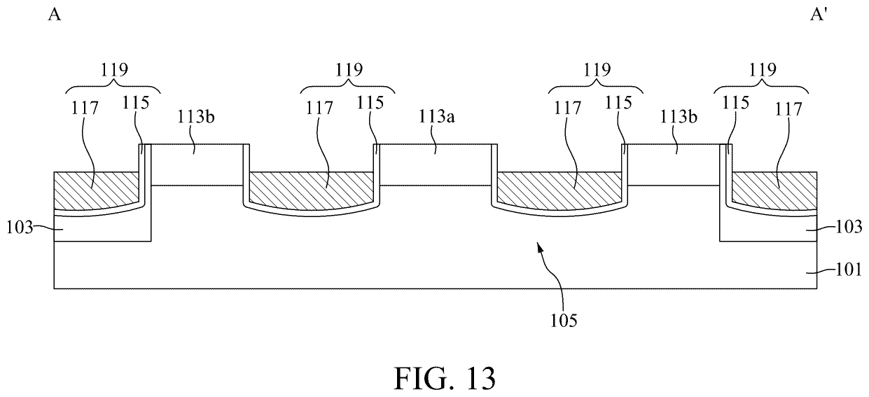

Next, the word lines 119 (i.e., the gate structures) are formed in the trenches 110, as shown in FIGS. 12 and 13 in accordance with some embodiments. The respective step is illustrated as the step S13 in the method 10 shown in FIG. 6. In some embodiments, the word lines 119 include the gate dielectric layers 115 and the gate electrodes 117.

In some embodiments, the gate dielectric layers 115 are made of silicon oxide, silicon nitride, silicon oxynitride, a dielectric material with high dielectric constant (high-k), or a combination thereof, and the gate electrodes 117 are made of a conductive material such as aluminum (Al), copper (Cu), tungsten (W), titanium (Ti), tantalum (Ta), or may be a multi-layer structure including any combination of the above materials. In some embodiments, barrier layers (not shown) are formed between the gate dielectric layers 115 and the gate electrodes 117.

The formation of the gate dielectric layers 115 may include conformally depositing a gate dielectric material (not shown) over the inner surfaces of the trenches 110 and the top surface of the semiconductor substrate 101, and planarizing the gate dielectric material to expose the top surface of the semiconductor substrate 101. After the gate dielectric layers 115 are formed, the formation of the gate electrodes 117 may include depositing a gate electrode material (not shown) over the gate dielectric layers 115, and recessing the gate electrode material to form the gate electrodes 117.

The deposition process of the gate dielectric material may include a chemical vapor deposition (CVD) process, a physical vapor deposition (PVD) process, an ALD process, a spin-coating process, or another applicable process. The planarization process of the gate dielectric material may be a chemical mechanical polishing (CMP) process. The deposition processes of the gate electrode material may include one or more deposition processes, such as a CVD process, a PVD process, an ALD process, a plasma enhanced chemical vapor deposition (PECVD) process, a metal organic chemical vapor deposition (MOCVD) process, a plating process, a sputtering process or another applicable deposition process. The gate electrode material may be recessed through an etch-back process, such that the top surfaces of the gate electrodes 117 are lower than the top surface of the semiconductor substrate 101. The etch-back process may include a wet etching process, a dry etching process, or a combination thereof.

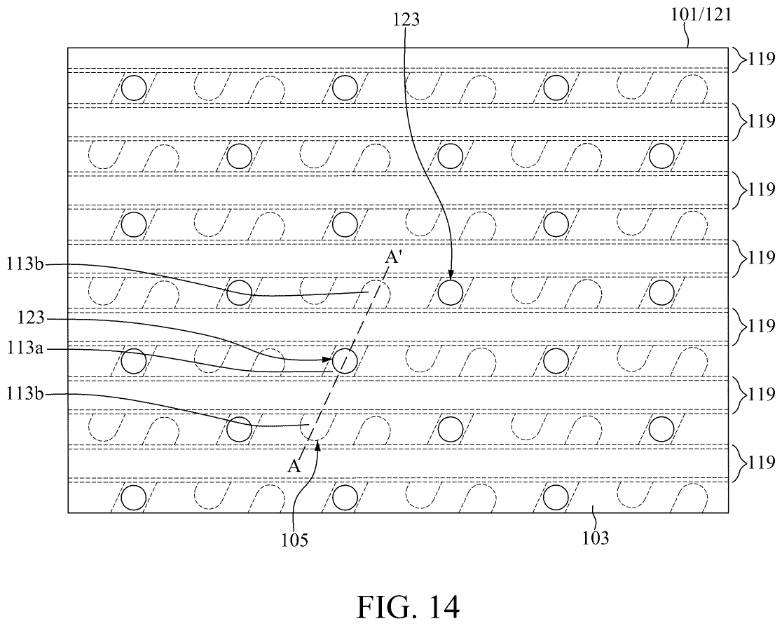

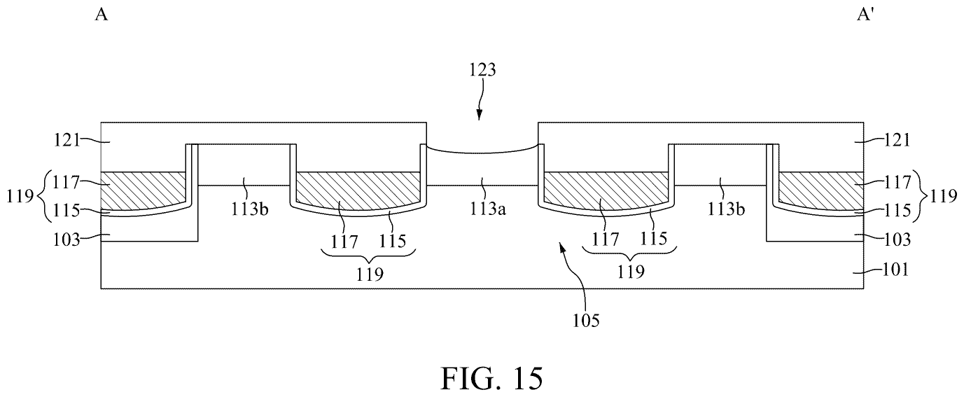

Subsequently, the dielectric cap layer 121 is formed covering the word lines 119, and the dielectric cap layer 121 is partially removed to form openings 123 exposing the source/drain regions 113a, as shown in FIGS. 14 and 15 in accordance with some embodiments. In some embodiments, portions of the dielectric cap layer 121 are surrounded by the gate dielectric layers 115. In some embodiments, the dielectric cap layer 121 is made of silicon oxide, silicon nitride, silicon oxynitride, or another applicable dielectric material.

In some embodiments, the dielectric cap layer 121 is formed by a CVD process, a PVD process, a spin coating process, another applicable process, or a combination thereof. In some embodiments, the openings 123 penetrating through the dielectric cap layer 121 are bit line openings. The formation of the openings 123 may include forming a patterned mask (not shown) over the dielectric cap layer 121, and etching the dielectric cap layer 121 by using the patterned mask as a mask. The etching process may be a wet etching process, a dry etching process, and a combination thereof. In some embodiments, portions of the source/drain regions 113a exposed by the patterned mask is removed by the etching process. After the openings 123 are formed, the pattered mask may be removed.

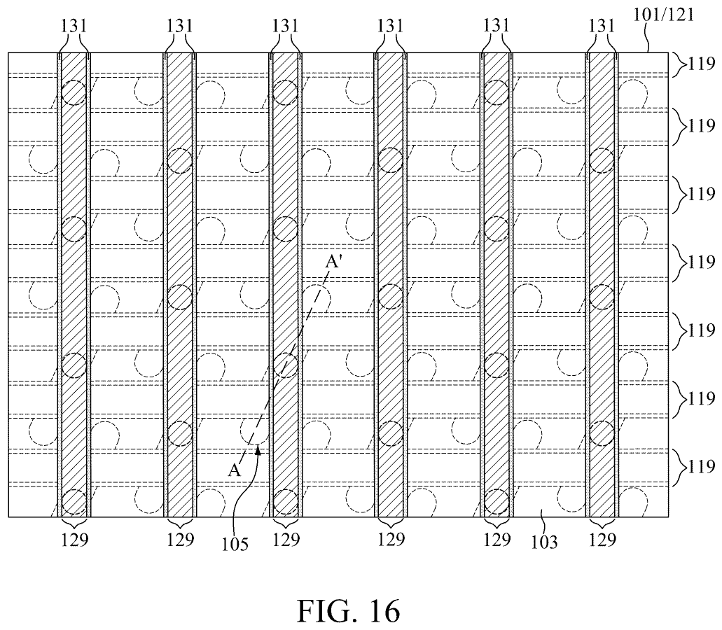

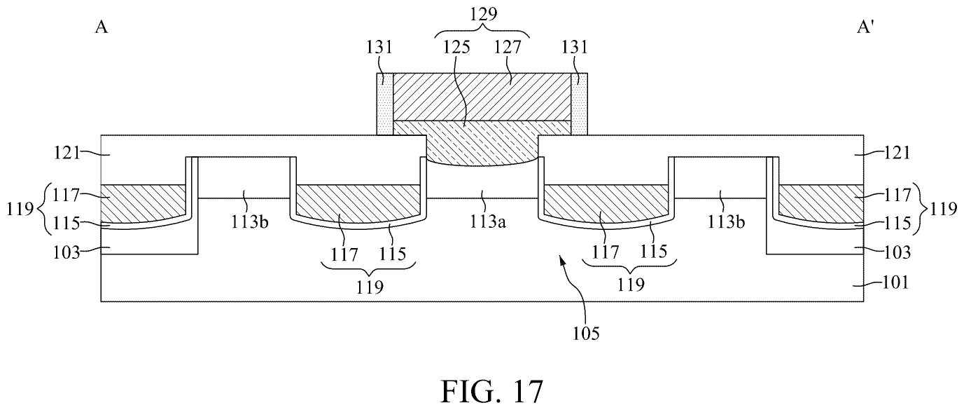

After the dielectric cap layer 121 is partially removed, the bit lines 129 are formed over the dielectric cap layer 121, and the openings 123 are filled by the bit lines 129, as shown in FIGS. 16 and 17 in accordance with some embodiments. The respective step is illustrated as the step S15 in the method 10 shown in FIG. 6. In some embodiments, the bit lines 129 are electrically connected to the source/drain regions 113a.

In some embodiments, the bit lines 129 include the lower bit line layers 125 and the upper bit line layers 127, and the openings 123 are filled by portions of the lower bit line layers 125. The formation of the bit lines 129 may include forming a lower bit line material (not shown) over the dielectric cap layer 121 and filling the openings 123, forming an upper bit line material (not shown) over the lower bit line material, forming a patterned mask (not shown) over the upper bit line material, and etching the upper bit line material and the lower bit line material by using the patterned mask as a mask. In some embodiments, the remaining portions of the lower bit line material (i.e., the lower bit line layers 125) and the remaining portions of the upper bit line material (i.e., the upper bit line layers 127) have aligned sidewalls. After the bit lines 129 are formed, the pattered mask may be removed.

Then, a plurality of dielectric spacers 131 are formed on the sidewalls of the bit lines 129, as shown in FIGS. 16 and 17 in accordance with some embodiments. In some embodiments, the dielectric spacers 131 are made of a doped spin-on-glass (SOG) material, such as phosphosilicate glass (PSG), borophosphosilicate glass (BPSG). In some embodiments, the dielectric spacers 131 are formed by a spin coating process, and a subsequent planarization process, such as a CMP process. The planarization process may be performed to expose the top surfaces of the bit lines 129.

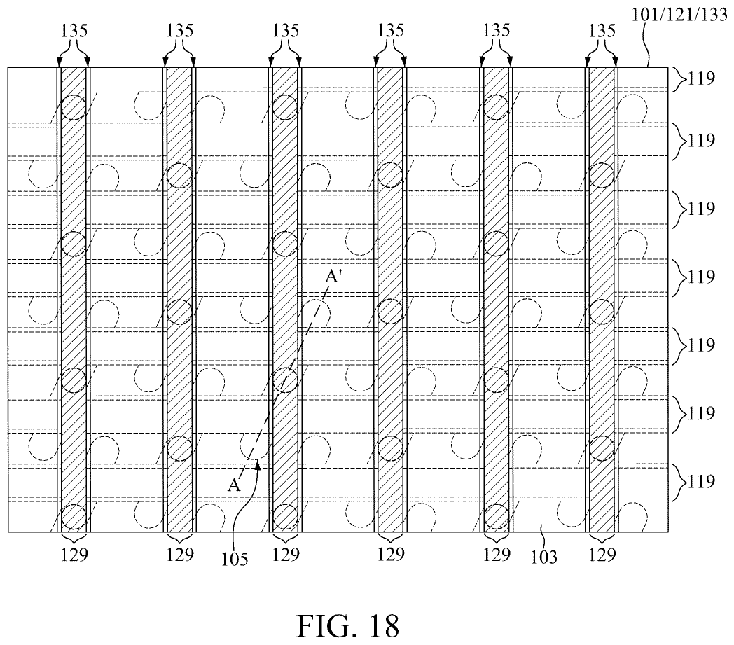

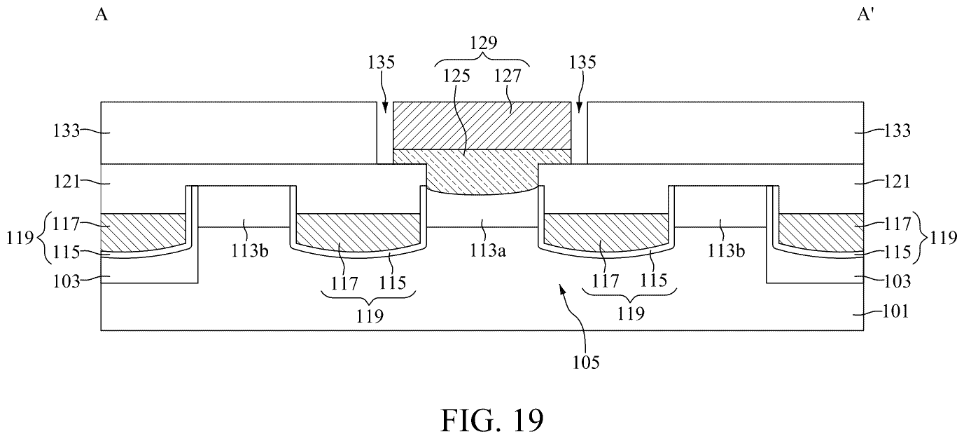

Next, the dielectric layer 133 is formed surrounding the dielectric spacers 131, and the dielectric spacers 131 are removed to form the air gaps 135 between the bit lines 129 and the dielectric layer 133, as shown in FIGS. 18 and 19 in accordance with some embodiments. In other words, the air gaps 135 are formed on the sidewalls of the bit lines 129, and the bit lines 129 are separated from the dielectric layer 133 by the air gaps 135, in accordance with some embodiments.

In some embodiments, the dielectric layer 133 is made of low-k dielectric materials. In some embodiments, the low-k dielectric materials have a dielectric constant (k value) less than about 4. Examples of the low-k dielectric materials include, but not limited to, silicon oxide, silicon nitride, silicon carbonitride (SiCN), silicon oxide carbonitride (SiOCN), fluorinated silica glass (FSG), carbon doped silicon oxide, amorphous fluorinated carbon, parylene, bis-benzocyclobutenes (BCB), or polyimide.

In some embodiments, the dielectric layer 133 are formed by a deposition process and a subsequent planarization process. The deposition process may include a CVD process, a PVD process, a spin coating process, or another applicable process. The planarization process may include a grinding process, a CMP process, an etching process, another applicable process, or a combination thereof. After the planarization process, the top surface of the dielectric layer 133 is coplanar with the top surfaces of the bit lines 129 and the top surfaces of the dielectric spacers 131.

In some embodiments, the dielectric spacers 131 are removed by a vapor phase hydrofluoric acid (VHF) etching process after the dielectric layer 133 is formed. During the etching process, VHF is used as an etchant, and the dielectric spacers 131 have a high selectivity against the dielectric layer 133. Therefore, the dielectric spacers 131 are removed by the etching process, while the dielectric layer 133 may be substantially left, such that the air gaps 135 are obtained.

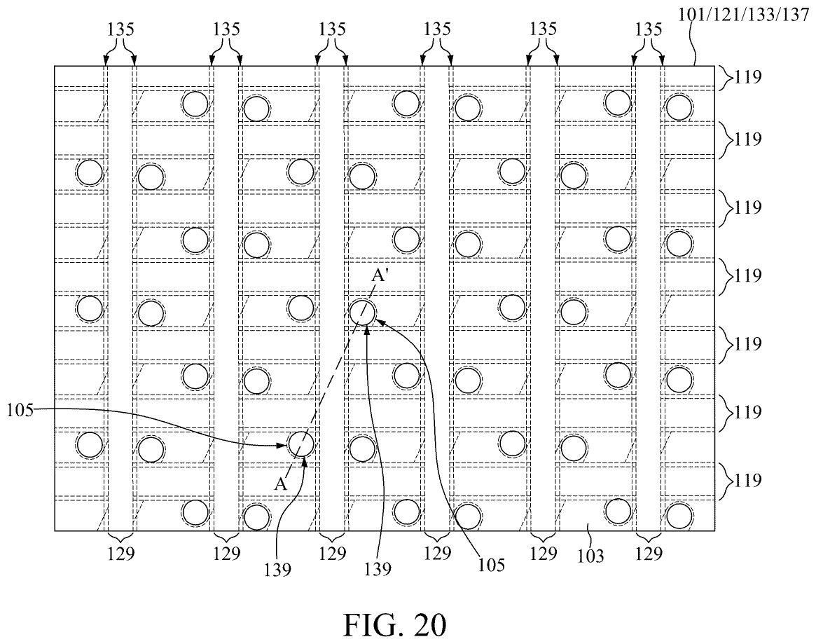

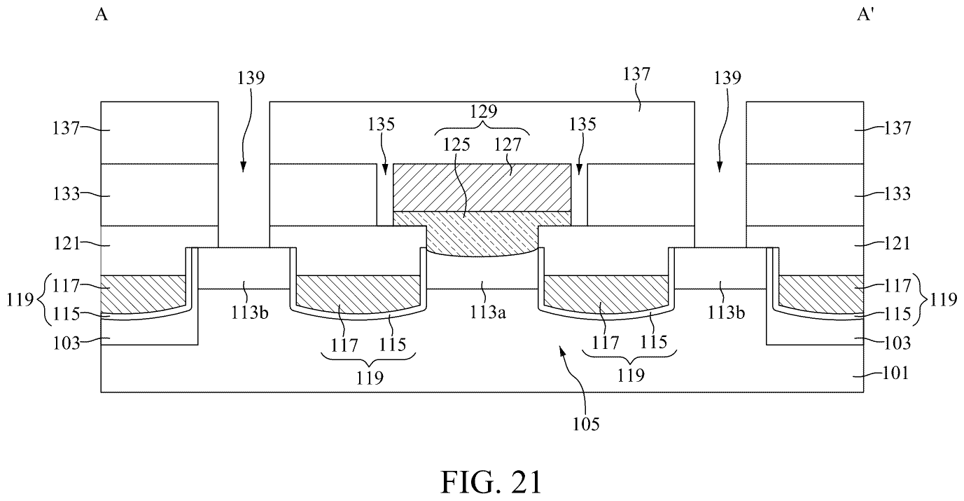

Subsequently, the dielectric layer 137 is formed over the dielectric layer 133 to seal the air gaps 135, and the dielectric cap layer 121 and the dielectric layers 133, 137 are partially removed to form openings 139 exposing the source/drain regions 113b, as shown in FIGS. 20 and 21 in accordance with some embodiments. Some materials and processes used to form the dielectric layer 137 are similar to, or the same as those used to form the dielectric layer 133, and details thereof are not repeated herein.

In some embodiments, the dielectric layer 137 is formed by a spin coating process, and the air gaps 135 with high aspect ratios are sealed by the dielectric layer 137 with the air gaps 135 remain therein rather than filled up by the dielectric layer 137. In some embodiments, the dielectric layer 137 extends into a top portion of the air gaps 135, such that a top surface of the air gaps 135 is lower than a top surface of the bit lines 129.

In some embodiments, the openings 139 penetrating through the dielectric cap layer 121 and the dielectric layers 133, 137 are capacitor contact openings. The formation of the openings 139 may include forming a patterned mask (not shown) over the dielectric layer 137, and etching the dielectric layer 137 by using the patterned mask as a mask. The etching process may be a wet etching process, a dry etching process, and a combination thereof. After the openings 139 are formed, the pattered mask may be removed.

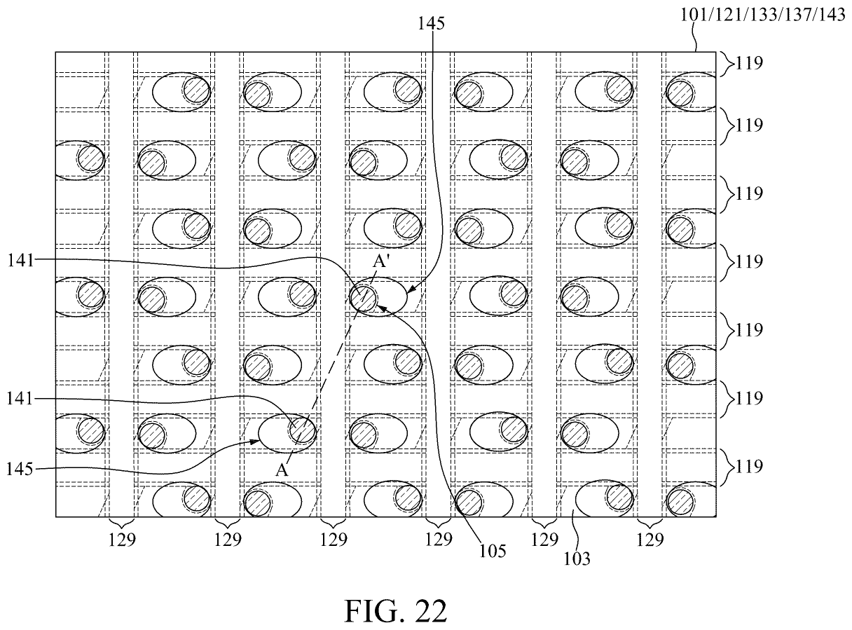

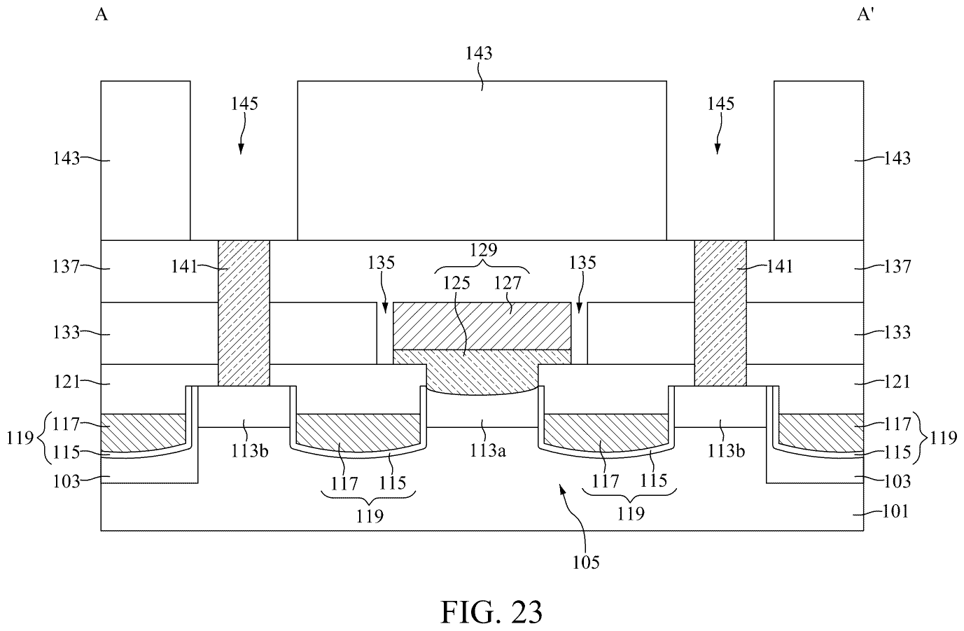

After the openings 139 are formed, the conductive contacts 141 are formed in the openings 139, and a dielectric layer 143 is formed over the dielectric layer 137 to cover the conductive contacts 141, as shown in FIGS. 22 and 23 in accordance with some embodiments. In some embodiments, the conductive contacts 141 are capacitor contacts, which electrically connect the source/drain regions 113b between the bit lines 129 to the subsequently formed capacitors 157.

In some embodiments, the conductive contacts 141 are made of a conductive material, such as copper (Cu), tungsten (W), aluminum (Al), titanium (Ti), tantalum (Ta), gold (Au), silver (Ag). The conductive contacts 141 may be formed by a deposition process and a subsequent planarization process. The deposition process may include a CVD process, a PVD process, a sputtering process, a plating process, or another applicable process. The planarization process may be a CMP process. Some materials and processes used to form the dielectric layer 143 are similar to, or the same as those used to form the dielectric layer 133, and details thereof are not repeated herein.

Still referring to FIGS. 22 and 23, a plurality of openings 145 are formed penetrating through the dielectric layer 143 to expose the conductive contacts 141, in accordance with some embodiments. The formation of the openings 145 may include forming a patterned mask (not shown) over the dielectric layer 143, and etching the dielectric layer 143 by using the patterned mask as a mask to expose the conductive contacts 141. The etching process may be a wet etching process, a dry etching process, and a combination thereof. After the openings 145 are formed, the pattered mask may be removed.

Next, referring back to FIGS. 1 and 2, the capacitors 157 are formed in the openings 145 in the dielectric layer 143, in accordance with some embodiments. In some embodiments, the bottom electrodes 151 of the capacitors 157 are formed over the source/drain regions 113b, the capacitor dielectric structures 153 of the capacitors 157 are formed over the bottom electrodes 151, and the top electrodes 155 of the capacitors 157 are formed over the capacitor dielectric structures 153. In some embodiments, the top electrodes 155, the capacitor dielectric structures 153, and the bottom electrodes 151 form the capacitors 157 electrically connected to the source/drain regions 113b. The respective steps are illustrated as the steps S17 to S21 in the method 10 shown in FIG. 6. Details of the formation of the capacitors 157 are described above in connection with FIGS. 3-5 and 7 and are not repeated herein. After the capacitors 157 are formed, the memory device 100 is obtained.

Embodiments of a memory device with multilayered capacitor dielectric structure and method for preparing the same are provided in the disclosure. In some embodiments, the memory device includes a capacitor having a multilayered capacitor dielectric structure. The capacitor dielectric structure includes a first metal oxide layer, a second metal oxide layer, and a third metal oxide layer. In some embodiments, the first metal oxide layer, the second metal oxide layer, and the third metal oxide layer include materials that are different from each other. In some embodiments, the first metal oxide layer includes ZrO₂, the second metal oxide layer include Al₂O₃, and the third metal oxide layer includes ZrO₂ doped with a dopant selected from the group consisting of Hf, Ta, La, Gd, Y, Sc, Ga, and lanthanide elements. As a result, the current leakage can be reduced while maintaining acceptable capacitance, which improving the overall device performance.

In one embodiment of the present disclosure, a memory device is provided. The memory device includes a semiconductor substrate having an active region, and a word line extending across the active region. The memory device also includes a first source/drain region and a second source/drain region disposed in the active region and at opposite sides of the word line, and a bit line disposed over and electrically connected to the first source/drain region. The memory device further includes a capacitor disposed over and electrically connected to the second source/drain region. The capacitor includes a bottom electrode, a top electrode, and a capacitor dielectric structure disposed between the bottom electrode and the top electrode. The capacitor dielectric structure includes a first metal oxide layer, a second metal oxide layer disposed over the first metal oxide layer, and a third metal oxide layer disposed over the second metal oxide layer. The first metal oxide layer, the second metal oxide layer, and the third metal oxide layer include materials that are different from each other.

In another embodiment of the present disclosure, a memory device is provided. The memory device includes a semiconductor substrate having an active region, and a word line extending across the active region. The memory device also includes a first source/drain region and a second source/drain region disposed in the active region and at opposite sides of the word line, and a bit line disposed over and electrically connected to the first source/drain region. The memory device further includes a capacitor disposed over and electrically connected to the second source/drain region. The capacitor includes a bottom electrode, a top electrode, and a capacitor dielectric structure disposed between the bottom electrode and the top electrode. The capacitor dielectric structure includes a first metal oxide layer, a second metal oxide layer disposed over the first metal oxide layer, and a third metal oxide layer disposed over the second metal oxide layer. The third metal oxide layer includes ZrO₂ doped with a first dopant selected from the group consisting of Hf, Ta, La, Gd, Y, Sc, Ga, and lanthanide elements.

In yet another embodiment of the present disclosure, a method for preparing a memory device is provided. The method includes forming a doped region in a semiconductor substrate, and forming a word line across the doped region such that a first source/drain region and a second source/drain region are formed in the doped region and at opposite sides of the word line. The method also includes forming a bit line over and electrically connected to the first source/drain region, and forming a capacitor over and electrically connected to the second source/drain region. The formation of the capacitor includes forming a bottom electrode, forming a capacitor dielectric structure over the bottom electrode, and forming a top electrode over the capacitor dielectric structure. The formation of the capacitor dielectric structure includes forming a first metal oxide layer, forming a second metal oxide layer over the first metal oxide layer, and forming a third metal oxide layer over the second metal oxide layer. The first metal oxide layer, the second metal oxide layer, and the third metal oxide layer include materials that are different from each other.

The embodiments of the present disclosure have some advantageous features. By using ZrO₂ doped with a dopant selected from the group consisting of Hf, Ta, La, Gd, Y, Sc, Ga, and lanthanide elements as a layer of the capacitor dielectric structure, the current leakage can be reduced while maintaining acceptable capacitance. As a result, the overall device performance can be improved.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. A method for preparing a memory device, comprising:
providing a semiconductor substrate having an active region;
forming a word line extending across the active region;
forming a first source/drain region and a second source/drain region in the active region and at opposite sides of the word line;
forming a bit line over and electrically connected to the first source/drain region; and
forming a capacitor over and electrically connected to the second source/drain region, wherein the capacitor comprises a bottom electrode, a top electrode, and a capacitor dielectric structure between the bottom electrode and the top electrode, and
wherein forming the capacitor dielectric structure comprises forming a first metal oxide layer, forming a second metal oxide layer over the first metal oxide layer, and forming a third metal oxide layer over the second metal oxide layer, and wherein the first metal oxide layer, the second metal oxide layer, and the third metal oxide layer comprise materials that are different from each other.

2. The method of claim 1, wherein the first metal oxide layer comprises ZrO₂, and the second metal oxide layer comprises Al₂O₃.

3. The method of claim 1, wherein the third metal oxide layer comprises ZrO₂ doped with a dopant selected from the group consisting of Hf, Ta, La, Gd, Y, Sc, Ga, and lanthanide elements.

4. The method of claim 3, wherein a concentration of the dopant in the third metal oxide layer is less than a concentration of Zr in the third metal oxide layer.

5. The method of claim 3, wherein an atomic percentage of the dopant in the third metal oxide layer is less than 20%.

6. The method of claim 1, wherein forming the capacitor dielectric structure further comprises forming a fourth metal oxide layer over the third metal oxide layer, and forming a fifth metal oxide layer over the fourth metal oxide layer, wherein the first metal oxide layer, the fourth metal oxide layer, and the fifth metal oxide layer comprise materials that are different from each other.

7. The method of claim 6, wherein the fourth metal oxide layer and the second metal oxide layer comprise Al₂O₃.

8. The method of claim 6, wherein the fifth metal oxide layer and the third metal oxide layer comprise ZrO₂ doped with a dopant selected from the group consisting of Hf, Ta, La, Gd, Y, Sc, Ga, and lanthanide elements.

9. A method for preparing a memory device, comprising:
providing a semiconductor substrate having an active region;
forming a word line extending across the active region;
forming a first source/drain region and a second source/drain region in the active region and at opposite sides of the word line;
forming a bit line over and electrically connected to the first source/drain region; and
forming a capacitor over and electrically connected to the second source/drain region, wherein the capacitor comprises a bottom electrode, a top electrode, and a capacitor dielectric structure between the bottom electrode and the top electrode, and
wherein forming the capacitor dielectric structure comprises forming a first metal oxide layer, forming a second metal oxide layer over the first metal oxide layer, and forming a third metal oxide layer over the second metal oxide layer, and wherein the third metal oxide layer comprises ZrO₂ doped with a first dopant selected from the group consisting of Hf, Ta, La, Gd, Y, Sc, Ga, and lanthanide elements.

10. The method of claim 9, wherein a crystallinity of the first metal oxide layer is higher than a crystallinity of the third metal oxide layer.

11. The method of claim 9, wherein the top electrode and the bottom electrode of the capacitor comprise TiN.

12. The method of claim 9, wherein the first metal oxide layer comprises ZrO₂, and the second metal oxide layer comprises Al₂O₃.

13. The method of claim 12, wherein the capacitor dielectric structure further comprises a fourth metal oxide layer over the third metal oxide layer, and the fourth metal oxide layer comprises Al₂O₃.

14. The method of claim 13, wherein forming the capacitor dielectric structure further comprises forming a fifth metal oxide layer over the fourth metal oxide layer, and the fifth metal oxide layer comprises ZrO₂ doped with a second dopant selected from the group consisting of Hf, Ta, La, Gd, Y, Sc, Ga, and lanthanide elements.

15. The method of claim 14, wherein the first dopant and the second dopant are the same.

16. A method for preparing a memory device, comprising:
forming a doped region in a semiconductor substrate;
forming a word line across the doped region such that a first source/drain region and a second source/drain region are formed in the doped region and at opposite sides of the word line;
forming a bit line over and electrically connected to the first source/drain region; and
forming a capacitor over and electrically connected to the second source/drain region, comprising:
forming a bottom electrode;
forming a capacitor dielectric structure over the bottom electrode, comprising:
forming a first metal oxide layer;
forming a second metal oxide layer over the first metal oxide layer; and
forming a third metal oxide layer over the second metal oxide layer, wherein the first metal oxide layer, the second metal oxide layer, and the third metal oxide layer comprise materials that are different from each other; and
forming a top electrode over the capacitor dielectric structure.

17. The method of claim 16, wherein the first metal oxide layer is formed by depositing ZrO₂, the second metal oxide layer is formed by depositing Al₂O₃, and the third metal oxide layer is formed by depositing ZrO₂ with a dopant selected from the group consisting of Hf, Ta, La, Gd, Y, Sc, Ga, and lanthanide elements.

18. The method of claim 17, further comprising:
repeating the forming the second metal oxide layer and the forming the third metal oxide layer one or more times before the top electrode is formed.

19. The method of claim 17, wherein the first metal oxide layer, the second metal oxide layer, and the third metal oxide layer are formed by atomic layer deposition (ALD) processes.

20. The method of claim 19, wherein a number of ALD cycles of the dopant occupies less than about 20% of a number of total ALD cycles of the third metal oxide layer.
